(19) United States
(12) Patent Application Publication
(10) Pub. No.: US 2024/0237195 A1
(43) Pub. Date: Jul. 11, 2024

(54) ELECTRONIC DEVICE AND MANUFACTURING METHOD OF ELECTRONIC DEVICE

(71) Applicant: InnoLux Corporation, Miao-Li County (TW)

(72) Inventors: Ker-Yih KAO, Miao-Li County (TW); Chung-Jyh LIN, Miao-Li County (TW); Chin-Ming HUANG, Miao-Li County (TW); Chien-Lin LAI, Miao-Li County (TW)

(73) Assignee: InnoLux Corporation, Miao-Li County (TW)

(21) Appl. No.: 18/534,734

(22) Filed: Dec. 11, 2023

Related U.S. Application Data
(60) Provisional application No. 63/437,125, filed on Jan. 5, 2023.

(30) Foreign Application Priority Data
Sep. 15, 2023 (CN) 202311188842.X

(51) Int. Cl. H05K 1/02; H05K 1/03; H05K 1/11; H05K 3/46

(52) U.S. Cl. CPC H05K 1/0272; H05K 1/0306; H05K 1/111; H05K 3/4644; H05K 2201/0209; H05K 2201/064; H05K 2201/066; H05K 2201/10636; H05K 2203/025

(57) ABSTRACT

An electronic device and a manufacturing method of the electronic device are provided by the present disclosure, wherein the electronic device includes at least one chip unit, a circuit structure electrically connected to the at least one chip unit, and a heat dissipation layer disposed at a side of the at least one chip unit opposite to the circuit structure, wherein the heat dissipation layer includes an insulating material layer and a plurality of silicon carbide particles, the insulating material layer clads the silicon carbide particles, and the silicon carbide particles have monocrystal structures.

### CROSS REFERENCE TO RELATED APPLICATION

This application claims the benefit of U.S. Provisional Application No. 63/437,125, filed on Jan. 5, 2023. The content of the application is incorporated herein by reference.

### BACKGROUND OF THE DISCLOSURE

### 1. Field of the Disclosure

The present disclosure relates to an electronic device and a manufacturing method thereof, and more particularly to an electronic device including heat dissipation layer and a manufacturing method thereof.

### 2. Description of the Prior Art

The epoxy molding compound (EMC) used in the current package structures includes epoxy resin and silicon dioxide particles filled in the epoxy resin. However, current epoxy molding compound has problems with poor heat dissipation or poor thermal conductivity, such that the performance or reliability of electronic elements in the packaging structure may be reduced. Therefore, to improve the heat dissipation of the package structure is still an important issue in the present field.

### SUMMARY OF THE DISCLOSURE

The present disclosure aims at providing an electronic device including heat dissipation layer and a manufacturing method of the electronic device, thereby improving heat dissipation of the electronic device.

An electronic device is provided by the present disclosure, wherein the electronic device includes at least one chip unit, a circuit structure electrically connected to the chip unit, and a heat dissipation layer disposed at a side of the chip unit opposite to the circuit structure, wherein the heat dissipation layer includes an insulating material layer and a plurality of silicon carbide particles, the insulating material layer clads the silicon carbide particles, and the silicon carbide particles have monocrystal structures.

A manufacturing method of an electronic device is provided by the present disclosure, wherein the manufacturing method includes providing a carrier; forming a circuit structure electrically connected to the chip unit; and disposing a heat dissipation layer at a side of the chip unit opposite to the circuit structure. The heat dissipation layer includes an insulating material layer and a plurality of silicon carbide particles, the insulating material layer clads the plurality of silicon carbide particles, and the plurality of silicon carbide particles have monocrystal structures.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates the flow chart of a manufacturing method of the electronic device according to the first embodiment of the present disclosure.

FIG. 3 to FIG. 5 schematically illustrate the manufacturing process of the electronic device according to the first embodiment of the present disclosure.

FIG. 6 schematically illustrates a cross-sectional view of an electronic device according to a second embodiment of the present disclosure.

FIG. 7 schematically illustrates the flow chart of a manufacturing method of the electronic device according to the second embodiment of the present disclosure.

FIG. 8 to FIG. 9 schematically illustrate the manufacturing process of the electronic device according to the second embodiment of the present disclosure.

FIG. 10 schematically illustrates a cross-sectional view of an electronic device according to a third embodiment of the present disclosure.

FIG. 11 schematically illustrates a cross-sectional view of an electronic device according to a fourth embodiment of the present disclosure.

FIG. 12 schematically illustrates a cross-sectional view of an electronic device according to a fifth embodiment of the present disclosure.

FIG. 13 schematically illustrates a cross-sectional view of an electronic device according to a sixth embodiment of the present disclosure.

FIG. 14 schematically illustrates a cross-sectional view of an electronic device according to a seventh embodiment of the present disclosure.

FIG. 15 schematically illustrates the flow chart of a manufacturing method of the electronic device according to the seventh embodiment of the present disclosure.

FIG. 16 schematically illustrates a cross-sectional view of an electronic device according to a seventh embodiment of the present disclosure.

FIG. 17 schematically illustrates a cross-sectional view of an electronic device according to an eighth embodiment of the present disclosure.

FIG. 18 schematically illustrates a cross-sectional view of an electronic device according to a ninth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

In the present disclosure, when an element is said to be between an element A and an element B, it can be interpreted as the element at least partially overlapping the element A and the element B in the top view direction of the electronic device.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

The term “between a value A and a value B” is to be interpreted as including value A and value B or conditions containing at least one of value A and value B, as well as other values between value A and value B.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a power module, a display device, a sensing device, a back-light device, an antenna device, a tiled device, a semiconductor device or other suitable electronic devices, but not limited thereto. The electronic device of the present disclosure may include any suitable device applied to the above-mentioned devices. The electronic device of the present disclosure may include a semiconductor package device. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device or a non-liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an in-organic light emitting diode. The in-organic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The manufacturing process of the electronic device of the present disclosure may for example be applied to wafer-level package (WLP) manufacturing process or panel-level package (FOPLP) manufacturing process. The WLP manufacturing process or the FOPLP manufacturing process include the chip-first manufacturing process or the chip-last manufacturing process, but not limited thereto.

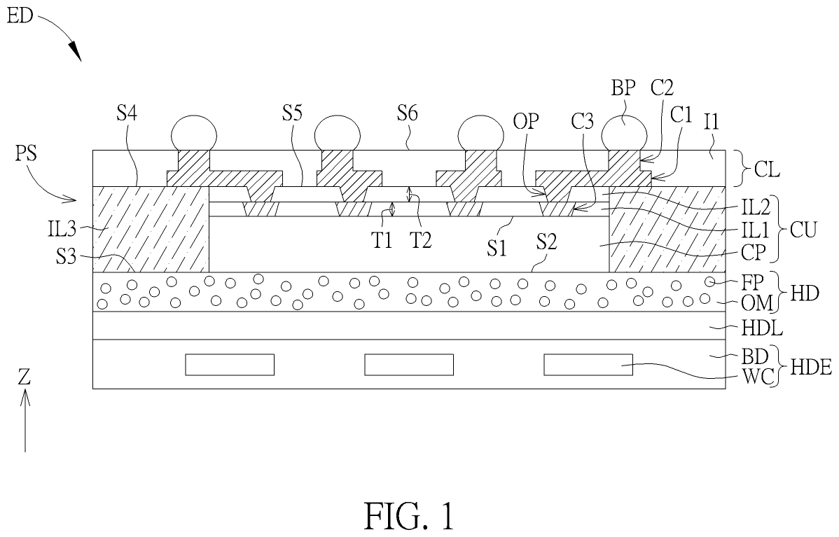

Referring to FIG. 1, FIG. 1 schematically illustrates a cross-sectional view of an electronic device according to a first embodiment of the present disclosure. According to the present embodiment, as shown in FIG. 1, the electronic device ED may include at least one chip unit CU, a circuit structure CL electrically connected to the chip unit CU and a heat dissipation layer HD, wherein the heat dissipation layer HD is disposed at a side of the chip unit CU opposite to the circuit structure CL. For example, FIG. 1 shows the structure that the electronic device ED includes one chip unit CU, but the present disclosure is not limited thereto. In other embodiments, the electronic device ED may include a plurality of chip units. The structures of the elements of the electronic device ED of the present embodiment will be detailed in the following.

According to the present embodiment, the chip unit CU may include a chip CP. The chip CP may include any suitable active element or passive element. For example, the chip CP may include printed circuit board (PCB), integrated circuit (IC), diode, resistor, capacitor, SMD elements, other suitable electronic elements or combinations of the above-mentioned electronic elements. The type of the electronic element included in the chip CP may be determined according to the type or use of the electronic device ED. In some embodiments, the electronic device ED may be a display device, and the chip CP may include light emitting diode, but not limited thereto. In some embodiments, the electronic device ED may be a sensing device, and the chip CP may include sensing elements, but not limited thereto. It should be noted that the chip CP may include one or more kinds of electronic element.

The chip unit CU may further include a first insulating layer IL1, wherein the first insulating layer IL1 may be disposed at a side of the chip CP. The chip CP may include at least one conductive pad (not shown) for electrically connecting the chip CP to other conductive elements, wherein the conductive pad of the chip CP may for example be located at a side of the surface S1 of the chip CP. For example, the at least one conductive pad of the chip CP may include a portion of transistor. The first insulating layer IL1 may be disposed at a side of the chip CP corresponding to the conductive pad, for example, the first insulating layer IL1 may be disposed on the surface S1 of the chip CP, but not limited thereto. In the present disclosure, the surface (that is, the surface S1) of the chip CP at which the conductive pad is disposed may be regarded as the active surface of the chip CP, and the surface (that is, the surface S2) of the chip CP opposite to the active surface may be regarded as the non-active surface (or rear surface) of the chip CP. In other words, the first insulating layer IL1 may be disposed corresponding to the active surface of the chip CP. The first insulating layer IL1 may serve as the passivation layer of the chip CP. The first insulating layer IL1 may include inorganic insulating materials, such as silicon oxide, silicon nitride, aluminum oxide or combinations of the above-mentioned materials, but not limited thereto. The first insulating layer IL1 may include a single-layer structure or a multi-layer structure.

The chip unit CU may further include a second insulating layer IL2, wherein the second insulating layer IL2 may be disposed at a side of the first insulating layer IL1 opposite to the chip CP. In other words, the first insulating layer IL1 may be disposed between the second insulating layer IL2 and the chip CP. The second insulating layer IL2 may cover the first insulating layer IL1. The second insulating layer IL2 may include any suitable organic materials, such as Ajinomoto build-up film (ABF), photosensitive polyimide (PSPI) or epoxy resin, but not limited thereto.

In the present embodiment, the first insulating layer IL1 has a thickness T1, and the second insulating layer IL2 has a thickness T2, wherein the thickness T1 may be less than the thickness T2. By making the second insulating layer IL2 include organic materials or making the thickness T2 of the second insulating layer IL2 greater than the thickness T1 of the first insulating layer IL1, the second insulating layer IL2 may provide protection, such that the possibility of breakage of the first insulating layer IL1 during the manufacturing process (such as the cutting process) of the electronic device ED may be reduced. According to some embodiments, the thermal expansion coefficient (CTE, ppm/° C.) of the first insulating layer IL1 may be less than the thermal expansion coefficient of the second insulating layer IL2, thereby providing protection or reducing warpage during the manufacturing process. According to some embodiments, the thickness T1 of the first insulating layer IL1 may be between 0.5 micrometers (μm) and 3 μm (that is, 0.5 μm≤T1≤3 μm), and the thickness T2 of the second insulating layer IL2 may be between 5 μm and 30 μm (that is, 5 μm≤T2≤30 μm).

It should be noted that the chip unit CU may further include other elements and/or layers, which is not limited to the structure shown in FIG. 1.

The electronic device ED may further include a third insulating layer IL3, wherein the third insulating layer IL3 may surround the chip unit CU. Specifically, the third insulating layer IL3 may surround the chip CP and the first insulating layer IL1 and the second insulating layers IL2 disposed on the chip CP. “The third insulating layer IL3 surrounds the chip unit CU” mentioned above may represent that the third insulating layer IL3 at least partially contacts a surface of the chip unit CU in a cross-sectional view of the electronic device ED. For example, the third insulating layer IL3 at least partially contacts the side surface of the chip unit CU in a cross-sectional view of the electronic device ED, but not limited thereto. For example, as shown in FIG. 1, the third insulating layer IL3 may directly contact side surfaces of the chip CP, the first insulating layer IL1 and the second insulating layer IL2. The third insulating layer IL3 of the present embodiment may serve as the encapsulation layer to encapsulate the chip unit CU. Therefore, the third insulating layer IL3 may provide the waterproof effect of the chip unit CU, thereby improving the reliability of the electronic device ED. The third insulating layer IL3 may include any suitable encapsulating material, such as epoxy molding compound (EMC), but not limited thereto. In the present embodiment, the top surface and the bottom surface of the third insulating layer IL3 may be aligned with the surfaces of the chip unit CU, but not limited thereto. Specifically, as shown in FIG. 1, the bottom surface S3 of the third insulating layer IL3 may be aligned with the surface S2 of the chip CP, and the top surface S4 of the third insulating layer IL3 may be aligned with the surface S5 of the second insulating layer IL2. In other words, the third insulating layer IL3 may expose the surface S2 of the chip CP, that is, rear surface of the chip CP. In other words, the third insulating layer IL3 may expose the chip unit CU.

According to the present embodiment, the circuit structure CL may be disposed adjacent to the active surface (that is, the surface S1) of the chip CP. Specifically, the circuit structure CL may be disposed on the top surface S4 of the third insulating layer IL3 and the surface S5 of the second insulating layer IL2. In such condition, the first insulating layer IL1 and the second insulating layer IL2 are disposed between the circuit structure CL and the chip CP. The circuit structure CL may include any suitable structure formed by stacking insulating layer(s) and conductive layer(s), wherein the stacking direction of the insulating layer(s) and the conductive layer(s) may be parallel to the normal direction of the electronic device ED, that is, the direction Z. For example, as shown in FIG. 1, the circuit structure CL may include a conductive layer C1, an insulating layer I1 disposed on the conductive layer C1 and covering the conductive layer C1, and a conductive layer C2 located in the insulating layer I1, wherein the conductive layer C2 is electrically connected to the conductive layer C1, but not limited thereto. The conductive layer C2 may for example be a under bump metallization (UBM). The conductive layer C1 and the conductive layer C2 may include any suitable conductive material, such as metal materials, but not limited thereto. The insulating layer I1 may include any suitable insulating material. It should be noted that the circuit structure CL shown in FIG. 1 is exemplary, and the present embodiment is not limited thereto. The circuit structure CL may include more conductive layers and more insulating layers.

The circuit structure CL may be electrically connected to the chip unit CU or be electrically connected to the chip CP of the chip unit CU. Specifically, the first insulating layer IL1 may include openings, and a conductive layer C3 may be disposed in the openings, wherein the conductive layer C3 may be disposed corresponding to the conductive pad (not shown) of the chip CP to be electrically connected to the conductive pad of the chip CP. The conductive layer C3 may include copper, aluminum, tantalum, but not limited to. For example, the conductive layer C3 may be I/O port. The second insulating layer IL2 may include openings OP, wherein the openings OP may correspond to the conductive layer C3 in the first insulating layer IL1 and expose the conductive layer C3. As shown in FIG. 1, the conductive layer C1 in the circuit structure CL may be filled into the openings OP to contact the conductive layer C3. Therefore, the chip CP may be electrically connected to the circuit structure CL. It should be noted that the chip CP may be electrically connected to the circuit structure CL through other suitable methods, which is not limited to the above-mentioned method.

In the present embodiment, the encapsulation layer (the third insulating layer IL3), the chip unit CU and the circuit structure CL may for example form a package structure PS. The package structure PS of the electronic device ED of the present embodiment may include a chip unit CU, but not limited thereto. In other embodiments, the package structure PS of the electronic device ED may include multiple chip units CU.

According to the present embodiment, the electronic device ED may further include at least one bonding pad BP, wherein the bonding pad BP may be disposed at a side of the circuit structure CL opposite to the chip unit CU. For example, the bonding pads BP may be disposed on the surface S6 of the insulating layer I1 opposite to the chip unit CU, but not limited thereto. The bonding pads BP may be electrically connected to the circuit structure CL. For example, the conductive layer C2 in the circuit structure CL may be disposed corresponding to the bonding pads BP, such that the bonding pads BP may be electrically connected to the conductive layer C2 and thereby being electrically connected to the conductive layer C1 in the circuit structure CL. The bonding pads BP may be electrically connected to the chip unit CU through the circuit structure CL. For example, the bonding pads BP may be electrically connected to the conductive pad of the chip CP through the conductive layers (such as the conductive layer C1 and the conductive layer C2) of the circuit structure CL and the conductive layer C3 in the first insulating layer IL1, but not limited thereto. The bonding pads BP may be electrically connected to any suitable external electronic unit (not shown). In such condition, the chip CP may be electrically connected to external electronic unit through the bonding pads BP. The external electronic unit may for example include printed circuit board, but not limited thereto. The bonding pads BP may include tin (Sn), copper (Cu), nickel (Ni), gold (Au), silver (Ag), alloys of the above-mentioned metals or other suitable materials. In some embodiments, the circuit structure CL may include a redistribution layer (RDL), such that the conductive pad of the chip CP may be electrically connected to the bonding pads BP at any suitable position through the layout design of the wires in the circuit structure CL. In some embodiments, the redistribution layer may redistribute the wires and/or increase the fan-out area of the wires, or the electronic elements may be electrically connected to each other through the redistribution layer.

According to the present embodiment, the electronic device ED includes a heat dissipation layer HD disposed at a side of the chip unit CU opposite to the circuit structure CL, that is, the circuit structure CL and the heat dissipation layer HD may respectively be disposed at two sides of the chip unit CU. In such condition, the chip unit CU may be disposed between the circuit structure CL and the heat dissipation layer HD. It should be noted that “the heat dissipation layer HD is disposed at a side of the chip unit CU opposite to the circuit structure CL” mentioned above may include the condition that at least a portion of the heat dissipation layer HD is disposed at a side of the chip unit CU opposite to the circuit structure CL. Specifically, the heat dissipation layer HD may be disposed adjacent to the rear surface (that is, the surface S2) of the chip CP. In the present embodiment, the heat dissipation layer HD may contact or at least partially contact the rear surface of the chip CP. For example, the heat dissipation layer HD may be a continuous layer extending on the rear surface of the chip CP and the bottom surface S3 of the third insulating layer IL3, but not limited thereto. In such condition, in the normal direction (that is, the direction Z) of the electronic device ED, the heat dissipation layer HD may at least partially overlap the chip CP, or in other words, the heat dissipation layer HD may at least partially overlap the rear surface of the chip CP.

According to the present embodiment, the heat dissipation layer HD may include an insulating material layer OM and filling particles FP filled in the insulating material layer OM. The insulating material layer OM may include organic materials, wherein the organic materials may include epoxy resin, acrylic resin, silicone, other suitable materials or combinations of the above-mentioned materials. In addition, in the present embodiment, the filling particles FP include silicon carbide. In other words, the heat dissipation layer HD may be formed by filling silicon carbide particles in the insulating material layer OM, that is, the heat dissipation layer HD includes a plurality of silicon carbide particles. The insulating material layer OM clads the filling particles FP. In other words, the filling particles FP may be dispersed in the insulating material layer OM, such that the insulating material layer OM may surround the filling particles FP. It should be noted that “the insulating material layer OM clads the filling particle FP” mentioned above may include the condition that the insulating material layer OM contacts at least a portion of the surface of the filling particle FP. In the present embodiment, the silicon carbide particles serve as filling particles FP may have monocrystal structure. The monocrystal structure of the silicon carbide particles may for example be confirmed through X-ray diffractometer (XRD) or other suitable equipment. In addition, in the present embodiment, the particle size of the silicon carbide particles may range from 0.02 millimeter (mm) to 55 mm, but not limited thereto. In other words, the particle size of the filling particles FP may range from 0.02 mm to 55 mm. In some embodiments, the particle size of the silicon carbide particles may range from 0.1 mm to 50 mm. In some embodiments, the particle size of the silicon carbide particles may range from 0.2 mm to 45 mm. According to the present embodiment, since the filling particles FP may include silicon carbide, wherein silicon carbide has good thermal conductivity, the heat dissipation layer HD including the filling particles FP may provide heat dissipating function of the chip unit CU (or the chip CP). Specifically, since the heat dissipation layer HD may at least partially contact the rear surface (the surface S2) of the chip CP, the heat generated when the chip CP operates may be conducted outward from the rear surface of the chip CP through the heat dissipation layer HD, such that the possibility that the performance of the chip CP is affected due to overheat of the chip CP may be reduced. The heat dissipation layer HD including the silicon carbide particles of the present embodiment may have a better heat dissipation effect compared with current epoxy molding compound (for example, including silicon dioxide particles). In addition, by making the silicon carbide particles in the heat dissipation layer HD have monocrystal structure, the heat dissipation effect of the heat dissipation layer HD may be improved.

As shown in FIG. 1, the electronic device ED of the present embodiment may optionally include a heat dissipation adhesive HDL and a heat dissipation element HDE in addition to the elements and the layers mentioned above, wherein the heat dissipation adhesive HDL may be disposed between the heat dissipation layer HD and the heat dissipation element HDE, but not limited thereto. Specifically, the heat dissipation element HDE may be attached to a side of the heat dissipation layer HD opposite to the chip unit CU through the heat dissipation adhesive HDL, that is, the heat dissipation layer HD may be disposed between the heat dissipation element HDE and the circuit structure CL. The heat dissipation adhesive HDL may include any adhesive material with high thermal conductivity, such as silver glue, but not limited thereto. In the present embodiment, the heat dissipation element HDE may include a water-cooling system and include a body BD and water channels WC disposed in the body BD. The body BD may include any material with high thermal conductivity, such as copper, but not limited thereto. Cooling liquid (such as water) may be included in the water channels WC, wherein the cooling liquid may circulate in the water channels WC. According to the present embodiment, the heat generated by the chip CP may be conducted from the rear surface of the chip CP to the heat dissipation element HDE through the heat dissipation layer HD and the heat dissipation adhesive HDL, but not limited thereto. In other words, the heat generated by the chip CP may be dissipated through the heat dissipation layer HD, the heat dissipation adhesive HDL and/or the heat dissipation element HDE. It should be noted that the electronic device ED may include other suitable heat dissipation elements, which is not limited to what is shown in FIG. 1.

It should be noted that the electronic device ED of the present embodiment ED may further include other suitable elements and/or layers, which is not limited to the structure shown in FIG. 1.

The manufacturing method of the electronic device ED of the present embodiment will be detailed in the following.

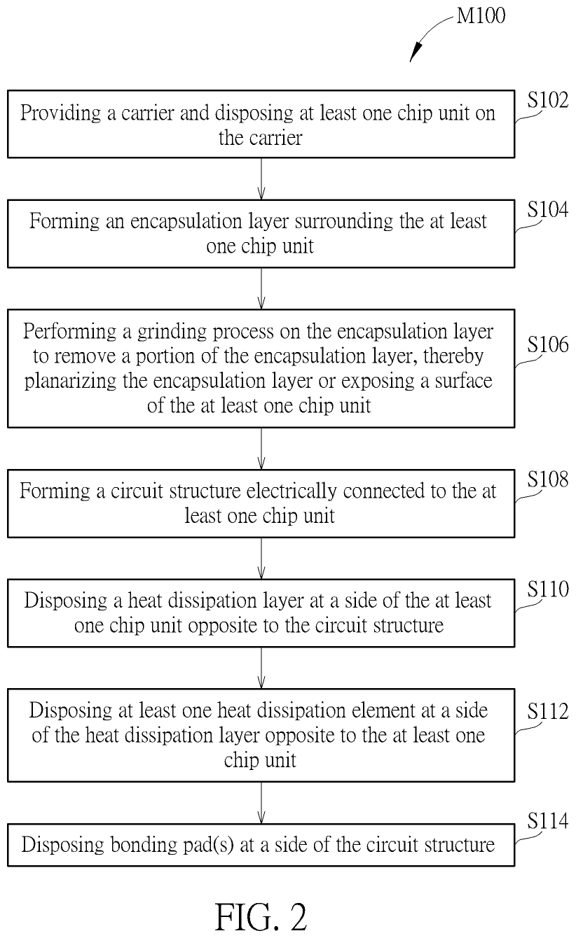

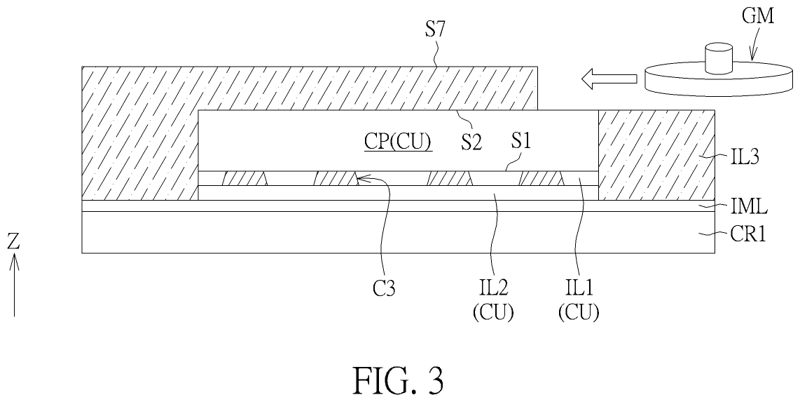

Referring to FIG. 2 to FIG. 5, FIG. 2 schematically illustrates the flow chart of a manufacturing method of the electronic device according to the first embodiment of the present disclosure, and FIG. 3 to FIG. 5 schematically illustrate the manufacturing process of the electronic device according to the first embodiment of the present disclosure. In the present embodiment, the manufacturing method M100 of the electronic device ED may include forming the chip unit CU at first, and then the circuit structure CL is formed. For example, the chip unit CU including the chip CP, the first insulating layer IL1 and the second insulating layer IL2 may be formed at first, and the chip unit CU may be encapsulated by the third insulating layer IL3. After that, the circuit structure CL may be disposed. As shown in FIG. 2, the manufacturing method M100 of the electronic device ED of the present embodiment may include the following steps:
S102: providing a carrier and disposing at least one chip unit on the carrier;
S104: forming an encapsulation layer surrounding the at least one chip unit;
S106: performing a grinding process on the encapsulation layer to remove a portion of the encapsulation layer, thereby planarizing the encapsulation layer or exposing a surface of the at least one chip unit;
S108: forming a circuit structure electrically connected to the at least one chip unit;
S110: disposing a heat dissipation layer at a side of the at least one chip unit opposite to the circuit structure;
S112: disposing at least one heat dissipation element at a side of the heat dissipation layer opposite to the at least one chip unit;
S114: disposing bonding pad(s) at a side of the circuit structure.

Each of the steps of the manufacturing method M100 of the electronic device ED will be detailed in the following.

As shown in FIG. 3, the manufacturing method M100 of the electronic device ED may include the step S102: providing at least one chip unit CU. Specifically, the chip CP may be provided at first, and the first insulating layer IL1 is disposed on the surface S1 of the chip CP. After that, openings may be formed in the first insulating layer IL1, and the conductive layer C3 may be disposed in the openings, wherein the conductive layer C3 may correspond to the conductive pad(s) (not shown) of the chip CP. After that, the second insulating layer IL2 may be disposed on the surface of the first insulating layer IL1 opposite to the chip CP. Therefore, the chip unit CU may be formed. The structural feature of the chip unit CU may refer to the contents mentioned above, and will not be redundantly described.

After that, the chip unit CU may be disposed on a carrier CR1. For example, the chip unit CU may be attached to a carrier CR1 through an intermediate layer IML, but not limited thereto. Specifically, the chip unit CU may be attached to the carrier CR1 through the intermediate layer IML in the way that the second insulating layer IL2 faces the carrier CR1 (that is, chip face down). According to some embodiments, the chip unit CU may be disposed on the carrier CR1 in the way of chip face up, but not limited thereto. In such condition, the second insulating layer IL2 may be located between the chip CP and the carrier CR1, and the surface S2 (that is, the rear surface) of the chip CP may face upward. The carrier CR1 may include any suitable supporting material, such as glass substrate, silicon substrate, BT carrier, steel plate or combinations of the above-mentioned materials, but not limited thereto. The intermediate layer IML may include any suitable adhesive material for temporarily fixing the chip unit CU on the carrier CR1, and the adhesive material may lose its adhesion through any physical or chemical ways during the manufacturing process.

After that, the step S104 may be performed to form the encapsulation layer that surrounds the chip unit CU. Specifically, after the chip unit CU is disposed on the carrier CR1, the third insulating layer IL3 may be formed on the carrier CR1, wherein the third insulating layer IL3 may surround the chip unit CU. The third insulating layer IL3 described herein is the encapsulation layer mentioned above. The third insulating layer IL3 may contact the side surface of the chip unit CU and cover the chip unit CU, thereby encapsulating the chip unit CU. In such condition, the third insulating layer IL3 (or the encapsulation layer) may include a surface S7 opposite to the carrier CR1, wherein the surface S7 may be higher than the surface S2 (that is, the rear surface of the chip CP) of the chip CP.

Then, the step S106 may be performed to perform a grinding process on the third insulating layer IL3 which serves as the encapsulation layer. Specifically, as shown in FIG. 3, after the third insulating layer IL3 is formed, a grinding tool GM or laser may be used to perform a polishing process or a grinding process on the surface S7 of the third insulating layer IL3, such that a portion of the third insulating layer IL3 may be removed to expose the surface S2 of the chip CP, that is, the rear surface of the chip CP is exposed. In other words, in the present disclosure, the surface S2 of the chip CP may be exposed by removing the portion of the third insulating layer IL3 protruded from (or higher than) the surface S2 of the chip. In addition, after the grinding process, the surface of the third insulating layer IL3 may be planarized to facilitate the subsequent processes, or to facilitate the disposition of other elements or layers on the third insulating layer IL3.

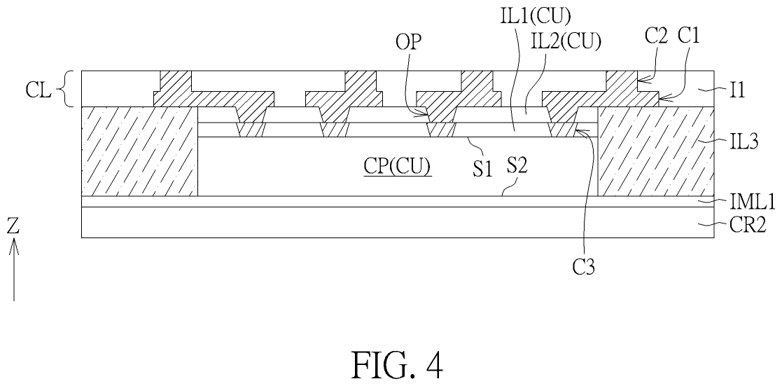

After that, referring to FIG. 4, the step S108 may be performed to form the circuit structure CL electrically connected to the chip unit CU. In detail, after the grinding process is performed on the third insulating layer IL3, an intermediate layer IML1 may be disposed on the rear surface (the surface S2) of the chip CP, and a carrier CR2 may be disposed on the intermediate layer IML1. In other words, the chip unit CU may be attached to the carrier CR2 through the intermediate layer IML1 in the way that the surface S2 of the chip CP faces the carrier CR2. After that, the formed structure may be flipped, such that the chip unit CU is disposed on the carrier CR2 (as shown in FIG. 4), and the intermediate layer IML and the carrier CR1 shown in FIG. 3 may be removed. In such condition, the chip CP is located between the second insulating layer IL2 and the carrier CR2, and the active surface (that is, the surface S1) of the chip CP may face upward. After that, a portion of the second insulating layer IL2 may be removed to form the openings OP, wherein the openings OP may expose at least a portion of the conductive layer C3. The removing process of the second insulating layer IL2 may include photolithography, development, dry etching, wet etching, laser drilling, mechanical drilling, cleaning or other suitable processes to make sure that the second insulating layer IL2 is removed, thereby preventing the electrical characteristics from being affected. After that, the conductive layer C1 may be disposed on the third insulating layer IL3 and the second insulating layer IL2. The conductive layer C1 may be disposed through any suitable process, such as sputtering, electroplating or chemical plating, but not limited thereto. The conductive layer C1 may be filled into the openings OP and contact the conductive layer C3, thereby being electrically connected to the conductive pad of the chip CP. According to some embodiments, the step of forming the openings OP in the second insulating layer IL2 may be performed before the chip unit CU is attached to the carrier CR1, but not limited thereto. The conductive layer C1 may be a patterned layer. Specifically, an entire layer of the material of the conductive layer C1 may be disposed on the third insulating layer IL3 and the second insulating layer IL2 at first, and a patterning process may be performed according to the demands of the design of the wires of the electronic device ED to form the conductive layer C1. The pattering process mentioned above may include photolithography, dry etching, wet etching, development or other suitable processes, but not limited thereto. After the conductive layer C1 is formed, the insulating layer I1 may be disposed on the third insulating layer IL3 and the second insulating layer IL2, wherein the insulating layer I1 may cover the conductive layer C1. After that, the conductive layer C2 may be formed in the insulating layer I1, wherein the conductive layer C2 may be electrically connected to the conductive layer C1. According to some embodiments, after the conductive layer C1 is formed, the conductive layer C2 may be formed on the conductive layer C1, and the insulating layer I1 covering the conductive layer C1 and the conductive layer C2 is provided. After that, the conductive layer C2 may be exposed through the processes such as mechanical grinding, laser, etching, cleaning, and the like, but not limited thereto. The disposition position of the conductive layer C2 may correspond to the disposition position of the bonding pads (that is, the bonding pads BP shown in FIG. 1) disposed in the subsequent process. Therefore, the circuit structure CL electrically connected to the chip unit CU may be formed. According to some embodiments, the surface of the conductive layer C2 may be higher than or lower than the surface of the insulating layer I1, or the surface of the conductive layer C2 may be coplanar with the surface of the insulating layer I1, but not limited thereto.

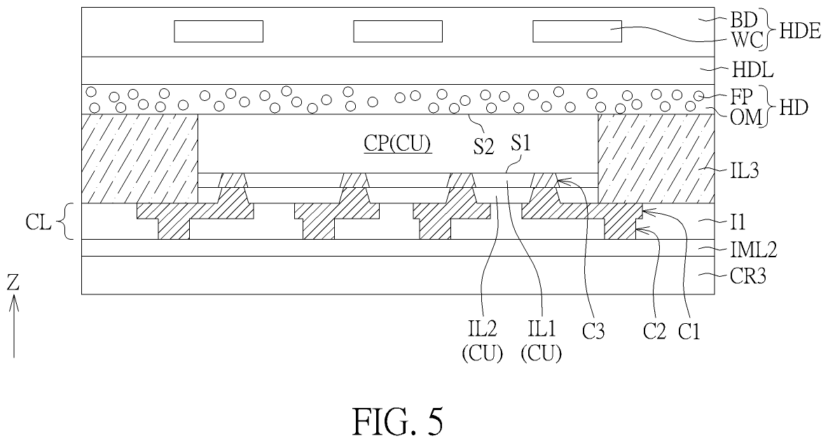

After that, as shown in FIG. 5, the step S110 may be performed to dispose the heat dissipation layer HD at a side of the chip unit CU opposite to the circuit structure CL. In detail, after the circuit structure CL is formed, an intermediate layer IML2 may be disposed on the circuit structure CL, and a carrier CR3 may be disposed on the intermediate layer IML2. After that, the formed structure may be flipped, such that the chip unit CU is disposed on the carrier CR3, and the intermediate layer IML1 and the carrier CR2 may be removed. In such condition, the surface S2 (that is, the rear surface) of the chip CP may face upward and be exposed. After that, the heat dissipation layer HD may be disposed on the surface S2 of the chip CP. The heat dissipation layer HD disposed on the surface S2 of the chip CP may at least partially contact the exposed surface S2 of the chip CP. Therefore, the heat dissipation function of the chip unit CU may be provided through the heat dissipation layer HD. The structural feature of the heat dissipation layer HD may refer to the contents mentioned above, and will not be redundantly described.

The manufacturing method M100 of the electronic device ED may optionally include the step S112: disposing at least one heat dissipation element at a side of the heat dissipation layer HD opposite to the chip unit CU. For example, as shown in FIG. 5, after the heat dissipation layer HD is disposed, the heat dissipation element HDE may be attached to a side of the heat dissipation layer HD opposite to the chip unit CU through the heat dissipation adhesive HDL, but not limited thereto. In other embodiments, any suitable heat dissipation element may be disposed at a side of the heat dissipation layer HD opposite to the chip unit CU. The structural features of the heat dissipation adhesive HDL and the heat dissipation element HDE may refer to the contents mentioned above, and will not be redundantly described.

The manufacturing method M100 of the electronic device ED may include the step S114: disposing bonding pad(s) (shown in FIG. 1) at a side of the circuit structure (CL). Specifically, after the heat dissipation element HDE is disposed, the intermediate layer IML2 and the carrier CR3 may be removed at first, and the bonding pads BP may be disposed at a side of the circuit structure CL opposite to the chip unit CU. Therefore, the electronic device ED shown in FIG. 1 may thereby be formed. The bonding pads BP may be disposed corresponding to the conductive layer (such as the conductive layer C2) of the circuit structure CL, such that the bonding pads BP are electrically connected to the chip unit CU. Therefore, the chip unit CU can be electrically connected to the external electronic unit through the bonding pads BP. According to some embodiments, before the bonding pads BP are disposed, the manufacturing method M100 may further include a surface cleaning step. Specifically, the surface cleaning step may include processes such as dry etching, wet etching or other suitable cleaning ways to remove residue or oxides on the surface, but not limited thereto.

It should be noted that the above-mentioned steps included in the manufacturing method M100 are exemplary, and the present disclosure is not limited thereto. In some embodiments, other steps may be inserted between the steps in the manufacturing method M100 according to the demands. In addition, any step in the manufacturing method M100 may be adjusted in order or deleted according to the demands.

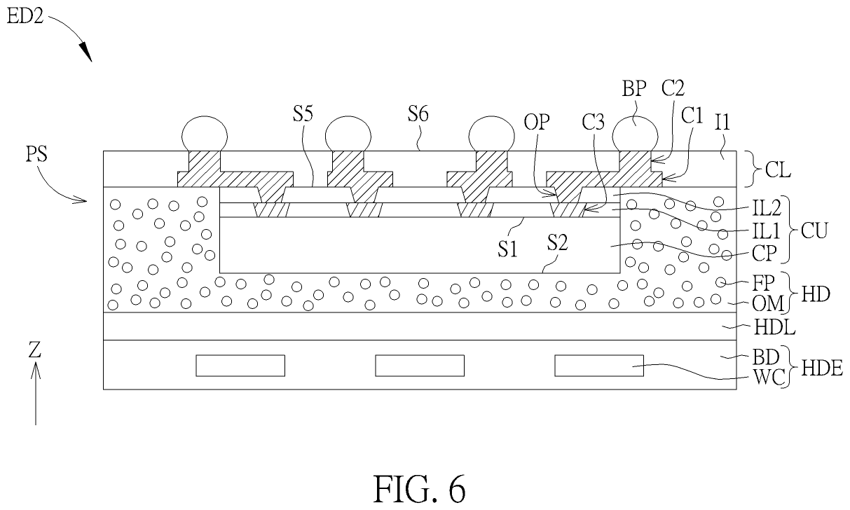

Referring to FIG. 6, FIG. 6 schematically illustrates a cross-sectional view of an electronic device according to a second embodiment of the present disclosure. According to the present embodiment, the heat dissipation layer HD of the electronic device ED2 may surround the chip unit CU. Specifically, the heat dissipation layer HD may contact side surfaces of the chip CP, the first insulating layer IL1 and the second insulating layer IL2. In addition, the heat dissipation layer HD may cover the chip unit CU, such that at least a portion of the heat dissipation layer HD may be disposed at a side of the chip unit CU opposite to the circuit structure CL. Therefore, the heat dissipation layer HD may at least partially contact the rear surface of the chip CP. In other words, the heat dissipation layer HD of the present embodiment may replace the third insulating layer IL3 shown in FIG. 1 and serve as the encapsulation layer to encapsulate the chip unit CU. In such condition, the thickness of the encapsulation layer may be greater than the thickness of the chip unit CU. Therefore, the package structure PS of the present embodiment may be formed by encapsulating the chip unit CU through the heat dissipation layer HD. Compared with current package structures, the electronic device ED2 of the present embodiment in which the heat dissipation layer HD is used to encapsulate the chip unit CU may have a better heat dissipation effect, thereby improving the performance or reliability of the electronic device ED2.

The manufacturing method of the electronic device ED2 of the present embodiment will be detailed in the following.

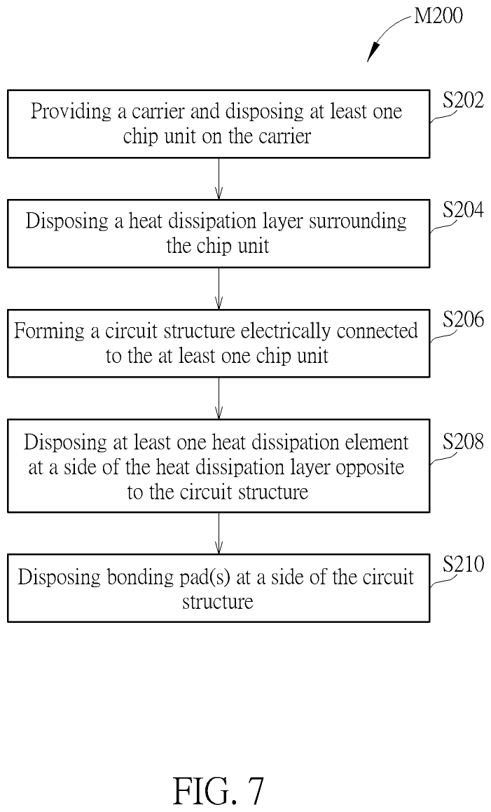

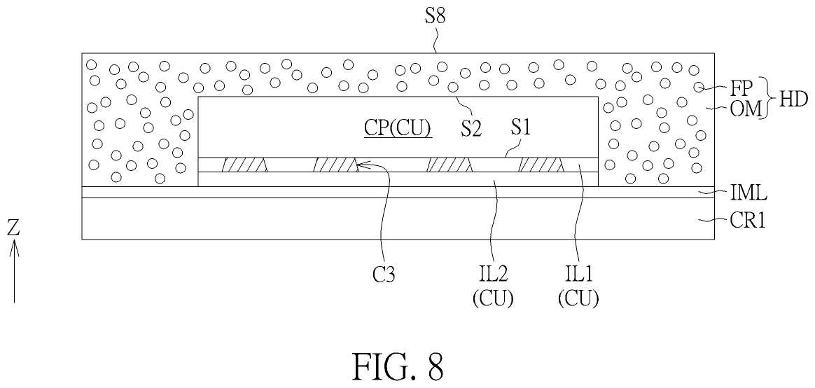

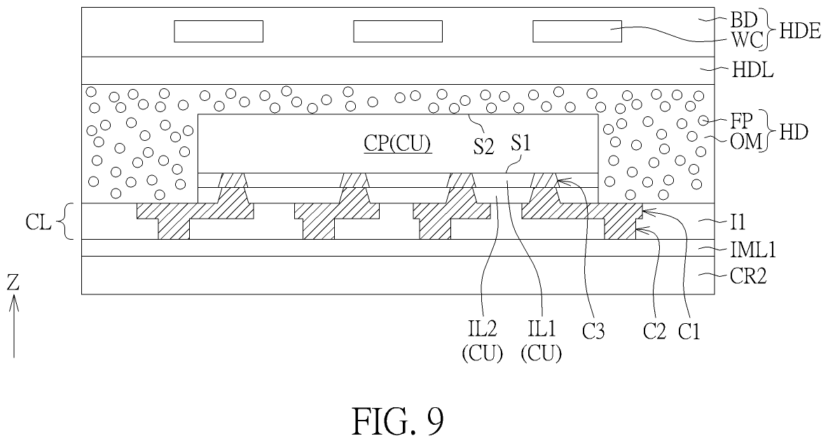

Referring to FIG. 7 to FIG. 9, FIG. 7 schematically illustrates the flow chart of a manufacturing method of the electronic device according to the second embodiment of the present disclosure, and FIG. 8 to FIG. 9 schematically illustrate the manufacturing process of the electronic device according to the second embodiment of the present disclosure. As shown in FIG. 7, the manufacturing method M200 of the electronic device ED2 of the present embodiment may include the following steps:
S202: providing a carrier and disposing at least one chip unit on the carrier;
S204: disposing a heat dissipation layer surrounding the chip unit;
S206: forming a circuit structure electrically connected to the at least one chip unit;
S208: disposing at least one heat dissipation element at a side of the heat dissipation layer opposite to the circuit structure;
S210: disposing bonding pad(s) at a side of the circuit structure.

Each of the steps of the manufacturing method M200 of the electronic device ED2 will be detailed in the following.

As shown in FIG. 8, the manufacturing method M200 of the electronic device ED2 may include the step S202: providing at least one chip unit CU. The forming method of the chip unit CU may refer to the contents of the manufacturing method M100 mentioned above, and will not be redundantly described. After the chip unit CU is formed, the chip unit CU may be disposed on the carrier CR1. For example, the chip unit CU may be attached to the carrier CR1 through the intermediate layer IML in the way that the second insulating layer IL2 faces the carrier CR1. In such condition, the second insulating layer IL2 may be located between the chip CP and the carrier CR1, and the surface S2 (that is, the rear surface) of the chip CP may face upward.

After that, the step S204 may be performed to dispose the heat dissipation layer HD, wherein the heat dissipation layer HD may surround the chip unit CU. As shown in FIG. 8, after the chip unit CU is disposed on the carrier CR1, the heat dissipation layer HD may be disposed on the carrier CR1, wherein the heat dissipation layer HD may cover the chip unit CU and contact the side surface of the chip unit CU. Specifically, the heat dissipation layer HD may cover the surface S2 of the chip CP. In such condition, at least a portion of the heat dissipation layer HD may be disposed on the surface S2 of the chip CP and contact the surface S2 of the chip CP. Therefore, the heat dissipation effect of the chip unit CU may be provided through the heat dissipation layer HD. In addition, the heat dissipation layer HD may be used to encapsulate the chip unit CU, and the electronic device ED2 may not include the third insulating layer IL3 in the above-mentioned embodiments. In some embodiments, although it is not shown in the figure, a grinding process may be performed on the heat dissipation layer HD after the heat dissipation layer HD is disposed. For example, a grinding process may be performed on the surface S8 of the heat dissipation layer HD opposite to the carrier CR1, but not limited thereto. Through the grinding process performed on the surface S8 of the heat dissipation layer HD, the flatness of the surface S8 of the heat dissipation layer HD may be improved to facilitate the disposition of other elements and/or layers (such as heat dissipation elements) on the heat dissipation layer HD. It should be noted that after the grinding process performed on the heat dissipation layer HD, the surface S8 of the heat dissipation layer HD may still be higher than the surface S2 of the chip CP, that is, the heat dissipation layer HD still includes the portion thereof disposed on the surface S2 of the chip CP.

The manufacturing method M200 of the electronic device ED2 may include the step S206: forming the circuit structure CL electrically connected to the chip unit CU. Specifically, based on the structure shown in FIG. 8, after the heat dissipation layer HD is disposed, an intermediate layer and a carrier (not shown) may be disposed on the surface S8 of the heat dissipation layer HD, the formed structure may be flipped, the intermediate layer IML and the carrier CR1 may be removed, and the circuit structure CL may be formed on the heat dissipation layer HD and the second insulating layer IL2. The forming method of the circuit structure CL of the present embodiment may refer to the contents of the manufacturing method M100 mentioned above, and will not be redundantly described. After the circuit structure CL is formed, at least a portion of the heat dissipation layer HD may be located at a side of the chip unit CU opposite to the circuit structure CL, that is, the heat dissipation layer HD may be regarded to be disposed at a side of the chip unit CU opposite to the circuit structure CL.

The manufacturing method M200 of the electronic device ED2 may optionally include the step S208: disposing at least one heat dissipation element at a side of the heat dissipation layer HD opposite to the circuit structure CL. Specifically, as shown in FIG. 9, after the circuit structure CL is formed, the intermediate layer IML1 and the carrier CR2 may be disposed on the circuit structure CL, and the formed structure may be flipped, such that the chip unit CU may be disposed on the carrier CR2, and the surface S2 of the chip CP may face upward. After that, the heat dissipation adhesive HDL may be disposed on the heat dissipation layer HD, and the heat dissipation element HDE may be attached to the heat dissipation layer HD through the heat dissipation adhesive HDL. Therefore, the structure shown in FIG. 9 may be formed.

The manufacturing method M200 of the electronic device ED2 may include the step S210: disposing bonding pads BP at a side of the circuit structure CL. Specifically, as shown in FIG. 9, after the heat dissipation element HDE is disposed, the intermediate layer IML1 and the carrier CR2 may be removed, and the bonding pads BP may be disposed at a side of the circuit structure CL opposite to the chip unit CU. Therefore, the electronic device ED2 shown in FIG. 6 may be formed.

It should be noted that the above-mentioned steps included in the manufacturing method M200 are exemplary, and the present disclosure is not limited thereto.

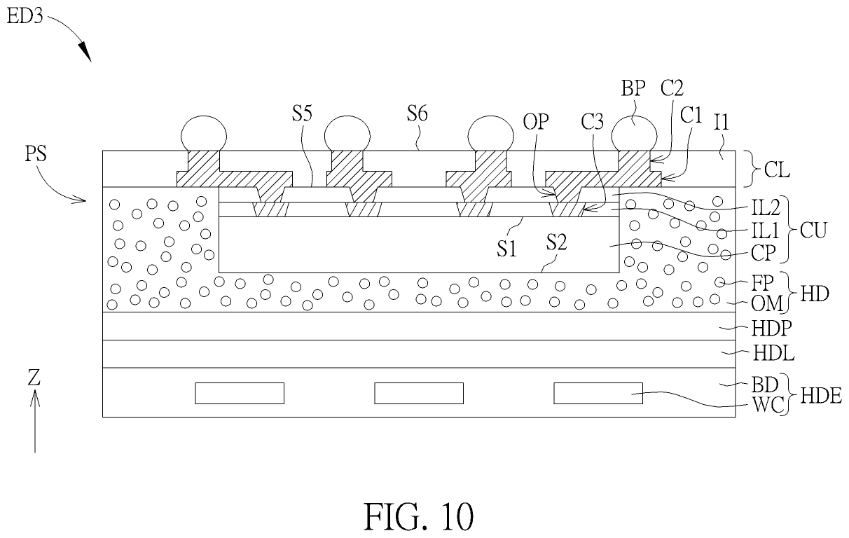

Referring to FIG. 10, FIG. 10 schematically illustrates a cross-sectional view of an electronic device according to a third embodiment of the present disclosure. One of the main differences between the electronic device ED3 of the present embodiment and the electronic device ED2 shown in FIG. 6 is that the electronic device ED3 of the present embodiment may further include the heat dissipation element HDP disposed between the heat dissipation adhesive HDL and the heat dissipation layer HD, wherein the heat dissipation element HDE may be attached to a side of the heat dissipation element HDP opposite to the heat dissipation layer HD through the heat dissipation adhesive HDL. In the present embodiment, the heat dissipation element HDP may for example include an aluminum nitride (AlN) substrate, but not limited thereto. In the present embodiment, the heat generated by the chip CP may be conducted from the rear surface (the surface S2) of the chip CP to the heat dissipation layer HD, the heat dissipation element HDP, the heat dissipation adhesive HDL and/or the heat dissipation element HDE, thereby being dissipated. It should be noted that although FIG. 10 shows the structure that the heat dissipation layer HD surrounds the chip unit CU, the present embodiment is not limited thereto.

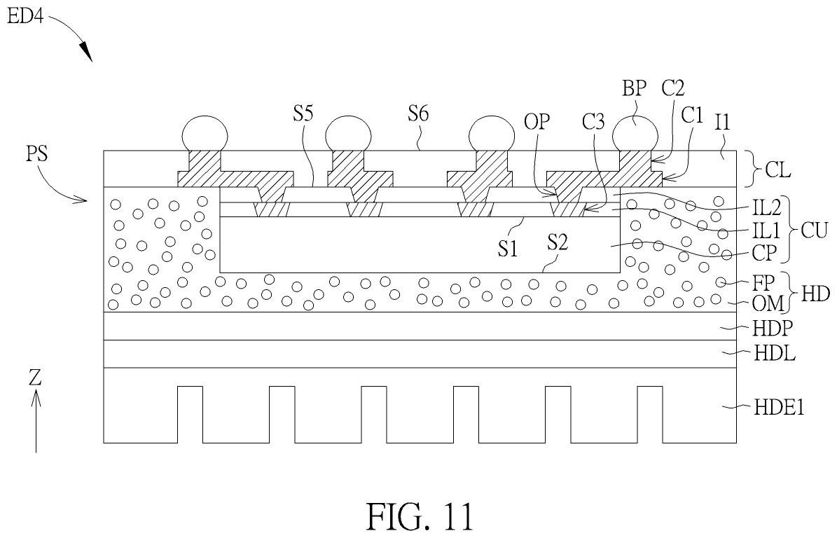

Referring to FIG. 11, FIG. 11 schematically illustrates a cross-sectional view of an electronic device according to a fourth embodiment of the present disclosure. According to the present embodiment, the electronic device ED4 may include a heat dissipation element HDE1, wherein the heat dissipation element HDE1 may be attached to a side of the heat dissipation element HDP opposite to the heat dissipation layer HD through the heat dissipation adhesive HDL. In the present embodiment, the heat dissipation element HDE1 may include a heat sink, but not limited thereto. Therefore, the heat generated by the chip CP may be conducted from the rear surface (the surface S2) of the chip CP to the heat dissipation layer HD, the heat dissipation element HDP, the heat dissipation adhesive HDL and/or the heat dissipation element HDE1, thereby being dissipated. It should be noted that although FIG. 11 shows the structure that the heat dissipation layer HD surrounds the chip unit CU, the present embodiment is not limited thereto.

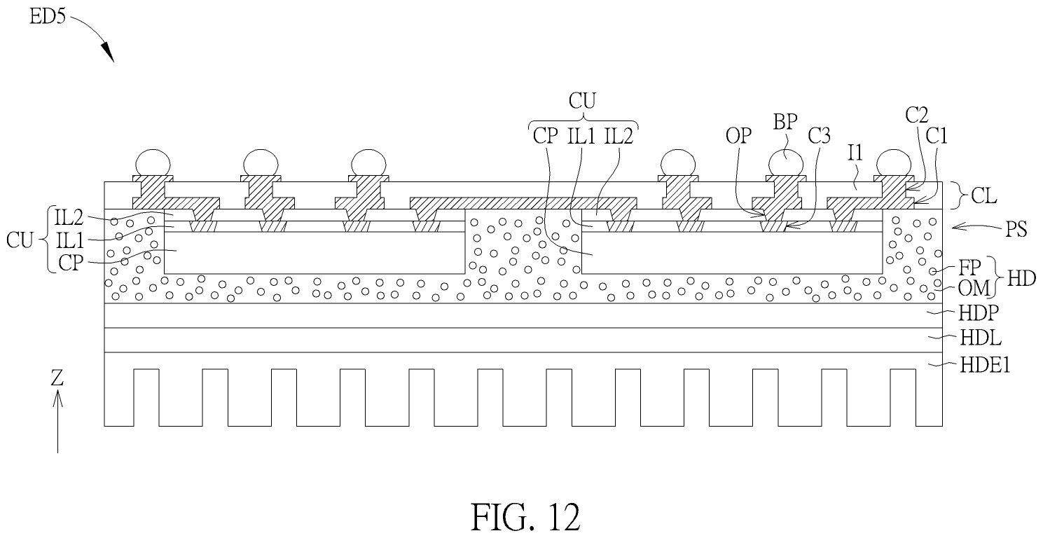

Referring to FIG. 12, FIG. 12 schematically illustrates a cross-sectional view of an electronic device according to a fifth embodiment of the present disclosure. One of the main differences between the electronic device ED5 of the present embodiment and the electronic devices of the above-mentioned embodiments is the design of the package structure. In detail, the package structures PS in the electronic devices of the above-mentioned embodiments may respectively include one chip unit CU and may for example be system on chip (SoC), and in the electronic device ED5 shown in FIG. 12, a plurality of chip units CU (for example, two chip units CU, but not limited thereto) may be included in a package structure PS. Specifically, the package structure PS of the electronic device ED5 may be formed by encapsulating two (or more) chip units CU through the encapsulation layer simultaneously. The encapsulation layer of the present embodiment may for example be the heat dissipation layer HD, and the heat dissipation layer HD may surround two (or more) chip units CU simultaneously, but not limited thereto. For example, the manufacturing method of the electronic device ED5 of the present embodiment may include disposing a plurality of chip units CU on a carrier at first, and then, the heat dissipation layer HD is disposed on the carrier and covers the plurality of chip units CU, but not limited thereto. In some embodiments, the encapsulation layer may be the third insulating layer IL3 mentioned above, and the heat dissipation layer HD may be disposed at a side of the rear surfaces of the plurality of chip units CU and at least partially contact the rear surfaces of the plurality of chip units CU. The chip units CU in a package structure PS may include the same or different types of electronic elements. Therefore, the package structure PS of the electronic device ED5 may be system in package (SiP). In the present embodiment, the chip units CU in the package structure PS may be electrically connected to each other. For example, the chip units CU may be electrically connected to each other through the conductive layer(s) (such as the conductive layer C1) in the circuit structure CL, but not limited thereto. The electronic device ED5 may further include the heat dissipation element(s) disposed at a side of the heat dissipation layer HD opposite to the chip units CU, such as the heat dissipation element HDE1, but not limited thereto. In addition, as shown in FIG. 12, the surface of the conductive layer C2 may be protruded from the surface of the insulating layer I1 in the present embodiment. Specifically, the conductive layer C2 may include a plurality of protruding portions protruded from the surface of the insulating layer I1, and the bonding pads BP may be disposed corresponding to the plurality of protruding portions of the conductive layer C2. It should be noted that the electronic device ED5 may include combinations of the above-mentioned heat dissipation elements, which is not limited to the structure shown in FIG. 12.

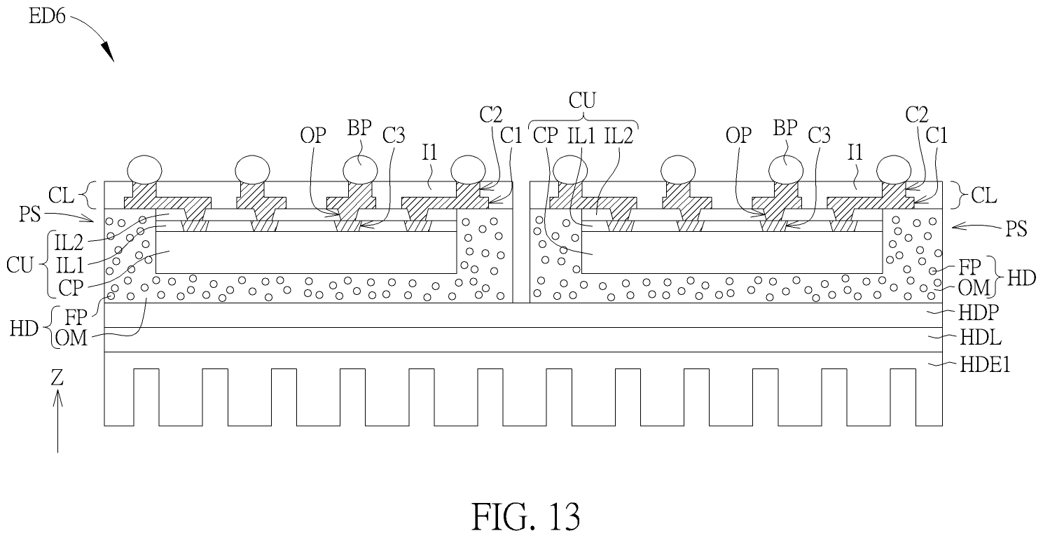

Referring to FIG. 13, FIG. 13 schematically illustrates a cross-sectional view of an electronic device according to a sixth embodiment of the present disclosure. According to the present embodiment, the electronic device ED6 may include a heat dissipation element and a plurality of package structures attached to the heat dissipation element. In other words, a plurality of package structures may be attached to a heat dissipation element to form the electronic device ED6. For example, as shown in FIG. 13, the electronic device ED6 may include a heat dissipation element HDE1 and two package structures PS attached to the heat dissipation element HDE1, but not limited thereto. That is, the electronic device ED6 may include a heat sink and a plurality of package structures PS disposed on the heat sink. In some embodiments, the heat dissipation element HDE1 of the electronic device ED6 may be replaced with the heat dissipation element HDE (the cooling system). Specifically, as shown in FIG. 13, a plurality of package structures PS may be disposed on a heat dissipation element HDP (such as aluminum nitride substrate), and the heat dissipation element HDP may be attached to the heat dissipation element HDE1 through the heat dissipation adhesive HDL, but not limited thereto. In some embodiments, the electronic device ED6 may not include the heat dissipation element HDP, that is, the package structures PS may be attached to the heat dissipation element HDE1 through the heat dissipation adhesive HDL. The package structure PS of the present embodiment may be formed by encapsulating the chip unit CU through the heat dissipation layer HD, but not limited thereto. In some embodiments, the package structure PS may be formed by encapsulating the chip unit CU through the third insulating layer IL3, and the electronic device ED6 may further include the heat dissipation layer HD disposed between the package structures PS and the heat dissipation adhesive HDL, wherein the heat dissipation layer HD may be a continuous layer or a patterned layer corresponding to the package structures PS. In addition, as shown in FIG. 13, in the circuit structure CL of the present embodiment, the surface of the conductive layer C2 may be lower than the surface of the insulating layer I1. Specifically, the conductive layer C2 may have concave surfaces, and the bonding pads BP may be disposed corresponding to the concave surfaces of the conductive layer C2.

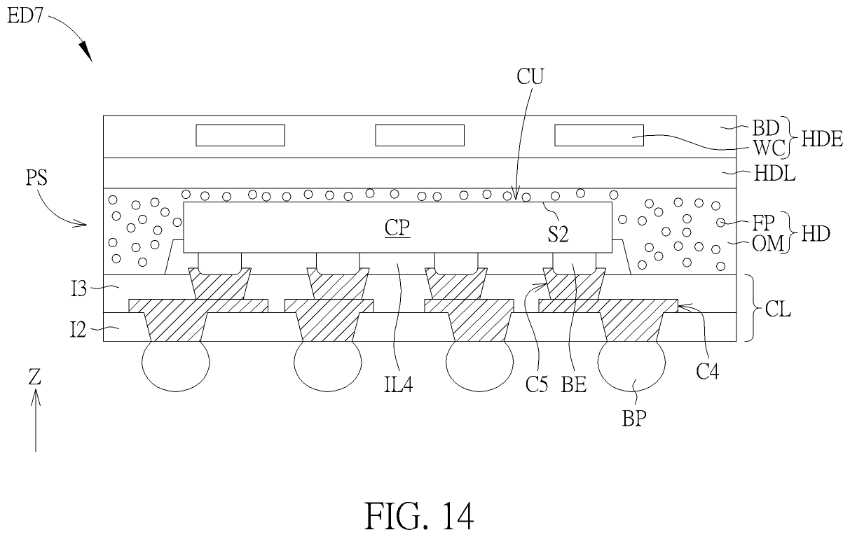

Referring to FIG. 14, FIG. 14 schematically illustrates a cross-sectional view of an electronic device according to a seventh embodiment of the present disclosure. According to the present embodiment, the forming method of the electronic device ED7 may include forming the circuit structure CL at first, and then forming the chip unit CU, which can be regarded as the redistribution layer (RDL)-first process. The circuit structure CL of the present embodiment may for example include an insulating layer I2, a conductive layer C4 disposed on the insulating layer I2, an insulating layer I3 disposed on the conductive layer C4 and covering the conductive layer C4 and a conductive layer C5 disposed in the insulating layer I3. The conductive layer C4 may for example be a back side under bonding metal which is filled into the openings (not labeled) of the insulating layer I2 and contacts the bonding pads BP, such that the circuit structure CL is electrically connected to the bonding pads BP. The conductive layer C5 may for example be a under bump metallization and may be electrically connected to the conductive layer C4. It should be noted that the circuit structure CL shown in FIG. 14 is exemplary, and the present embodiment is not limited thereto. After the circuit structure CL is formed, the chip unit CU may be disposed on the circuit structure CL, that is, the chip CP may be disposed on the circuit structure CL. In order to simplify the figure, the first insulating layer IL1 and the second insulating layer IL2 of the chip unit CU are omitted in FIG. 14, but not limited thereto. The chip CP may be electrically connected to the circuit structure CL through the bonding elements BE, for example, the chip CP may be electrically connected to the conductive layer C5 of the circuit structure CL, but not limited thereto. In some embodiments, the bonding elements BE may include copper pillars. In some embodiments, the bonding elements BE may include solder. The electronic device ED7 may optionally include an insulating layer IL4, wherein the insulating layer IL4 may surround the bonding elements BE and/or the chip unit CU. Specifically, after the chip unit CU is disposed on the circuit structure CL, the insulating layer IL4 may be disposed. The insulating layer IL4 may serve as the underfill layer to protect the bonding elements BE, but not limited thereto. In the present embodiment, the chip unit CU may be encapsulated through the heat dissipation layer HD to form the package structure PS, wherein the package structure PS may for example include a chip unit CU, but not limited thereto.

The electronic device ED7 may further include the heat dissipation layer HD, wherein the heat dissipation layer HD may be used to encapsulate the chip unit CU. Specifically, the heat dissipation layer HD may be disposed on the circuit structure CL and surround the chip unit CU and/or the insulation layer IL4. In addition, at least a portion of the heat dissipation layer HD may be disposed at a side of the chip unit CU opposite to the circuit structure CL. In other words, the heat dissipation layer HD may at least partially contact the rear surface (that is, the surface S2) of the chip CP. In addition, the electronic device ED7 may further include the heat dissipation element(s) disposed on the heat dissipation layer HD. For example, as shown in FIG. 14, the heat dissipation element HDE (the cooling system) may be attached to the heat dissipation layer HD through the heat dissipation adhesive HDL, but not limited thereto. In some embodiments, the heat dissipation element HDE may be replaced with the heat dissipation element HDE1 (the heat sink). Therefore, the heat generated by the chip CP may be conducted and dissipated from the rear surface of the chip CP through the heat dissipation layer HD, the heat dissipation adhesive HDL and the heat dissipation element HDE. It should be noted that the electronic device ED7 may include combinations of the above-mentioned heat dissipation elements, which is not limited to the structure shown in FIG. 14.

The manufacturing method of the electronic device ED7 of the present embodiment will be detailed in the following.

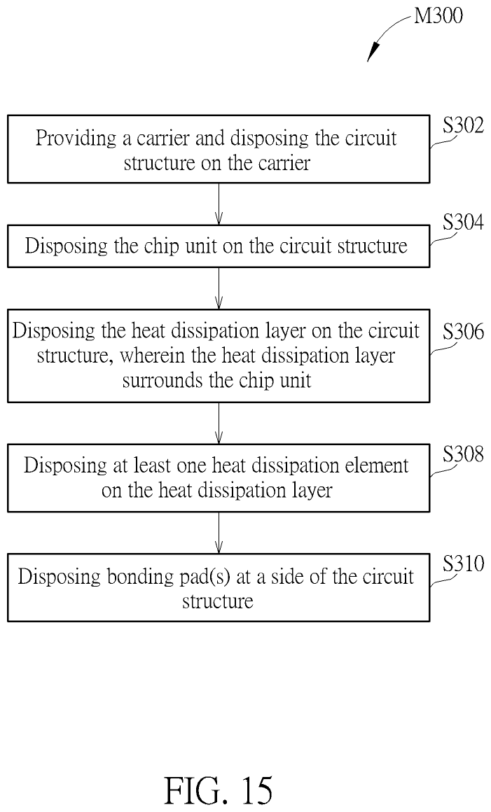

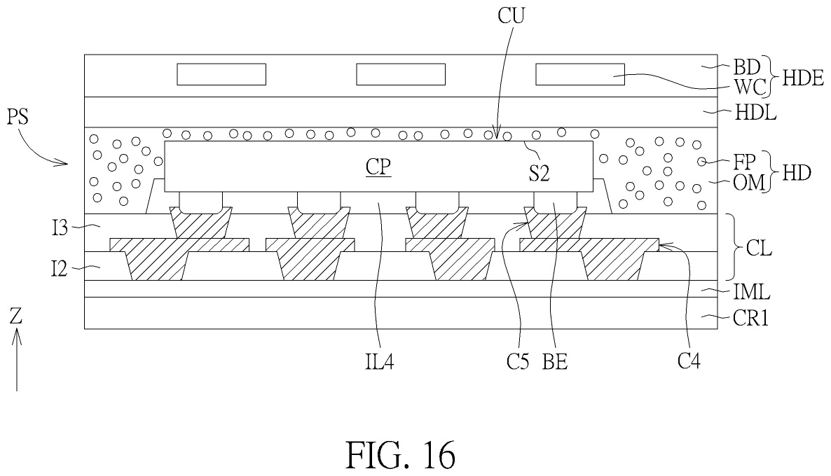

Referring to FIG. 15 to FIG. 16, FIG. 15 schematically illustrates the flow chart of a manufacturing method of the electronic device according to the seventh embodiment of the present disclosure, and FIG. 16 schematically illustrates a cross-sectional view of an electronic device according to a seventh embodiment of the present disclosure. As shown in FIG. 15, the manufacturing method M300 of the electronic device ED7 of the present embodiment may include the following steps:
S302: providing a carrier and disposing the circuit structure on the carrier;
S304: disposing the chip unit on the circuit structure;
S306: disposing the heat dissipation layer on the circuit structure, wherein the heat dissipation layer surrounds the chip unit;
S308: disposing at least one heat dissipation element on the heat dissipation layer;
S310: disposing bonding pad(s) at a side of the circuit structure.

Each of the steps of the manufacturing method M300 of the electronic device ED7 will be detailed in the following.

As shown in FIG. 16, the manufacturing method M300 of the electronic device ED7 may include the step S302: providing a carrier CR1 and disposing the circuit structure CL on the carrier CR1. Specifically, the circuit structure CL may be attached to the carrier CR1 through the intermediate layer IML. In some embodiments, the circuit structure CL may be formed on another carrier at first, and then, the circuit structure CL may be transferred to the carrier CR1. In some embodiments, the circuit structure CL may be directly formed on the carrier CR1. For example, the insulating layer I2 may be formed on the carrier CR1, and the insulating layer I2 may be patterned to form a plurality of openings (not shown). After that, the conductive layer C4 may be formed on the insulating layer I2, wherein the conductive layer C4 may be filled into the openings of the insulating layer I2. Then, the insulating layer I3 may be formed on the insulating layer I2, wherein the insulating layer I3 may cover the conductive layer C4. After that, a plurality of openings (not shown) may be formed in the insulating layer I3, and the conductive layer C5 may be formed in the openings of the insulating layer I3. Therefore, the circuit structure CL may be formed. It should be noted that the forming method of the circuit structure CL mentioned above is exemplary, and the present disclosure is not limited thereto.

The manufacturing method M300 of the electronic device ED7 may include the step S304: disposing the chip unit CU on the circuit structure CL. Specifically, as shown in FIG. 16, after the circuit structure CL is formed on the carrier CR1, the chip unit CU may be disposed on the circuit structure CL, wherein the disposition positions of the bonding elements BE correspond to the conductive layer (such as the conductive layer C5) of the circuit structure CL, such that the chip unit CU is electrically connected to the circuit structure CL through the bonding elements BE. The detailed structure of the chip unit CU may refer to the contents of the above-mentioned embodiments, and will not be redundantly described. After the chip unit CU is disposed, the insulating layer IL4 surrounding the bonding elements BE and/or the chip unit CU may further be disposed on the circuit structure CL.

The manufacturing method M300 of the electronic device ED7 may include the step S306: disposing the heat dissipation layer HD on the circuit structure CL, wherein the heat dissipation layer HD surrounds the chip unit CU. Specifically, as shown in FIG. 16, after the chip unit CU is disposed, the heat dissipation layer HD may be disposed on the circuit structure CL, wherein the heat dissipation layer HD may cover the chip unit CU and contact the side surface of the chip unit CU. The heat dissipation layer HD may cover the surface S2 of the chip CP, that is, at least a portion of the heat dissipation layer HD may be disposed on the surface S2 of the chip CP and contact the surface S2 of the chip CP. Therefore, the heat dissipation effect of the chip unit CU may be provided by the heat dissipation layer HD. In some embodiments, although it is not shown in the figure, a grinding process may be performed on the heat dissipation layer HD after the heat dissipation layer HD is disposed. For example, a grinding process may be performed on the surface of the heat dissipation layer HD opposite to the circuit structure CL to facilitate the disposition of other elements and/or layers (such as heat dissipation elements) on the heat dissipation layer HD, but not limited thereto.

The manufacturing method M300 of the electronic device ED7 may include the step S308: disposing at least one heat dissipation element on the heat dissipation layer HD. Specifically, as shown in FIG. 16, after the heat dissipation layer HD is disposed, the heat dissipation adhesive HDL may be disposed on the heat dissipation layer HD, and the heat dissipation element HDE may be attached to the heat dissipation layer HD through the heat dissipation adhesive HDL. That is, the heat dissipation element HDE is disposed at a side of the heat dissipation layer HD opposite to the circuit structure CL. Therefore, the structure shown in FIG. 16 may be formed.

The manufacturing method M300 of the electronic device ED7 may include the step S310: disposing bonding pads BP at a side of the circuit structure CL. Specifically, as shown in FIG. 16, after the heat dissipation element HDE is disposed, the intermediate layer IML and the carrier CR1 may be removed at first, and then, the bonding pads BP are disposed at a side of the circuit structure CL opposite to the chip unit CU. Therefore, the electronic device ED7 shown in FIG. 14 may be formed.

It should be noted that the above-mentioned steps included in the manufacturing method M300 are exemplary, and the present disclosure is not limited thereto.

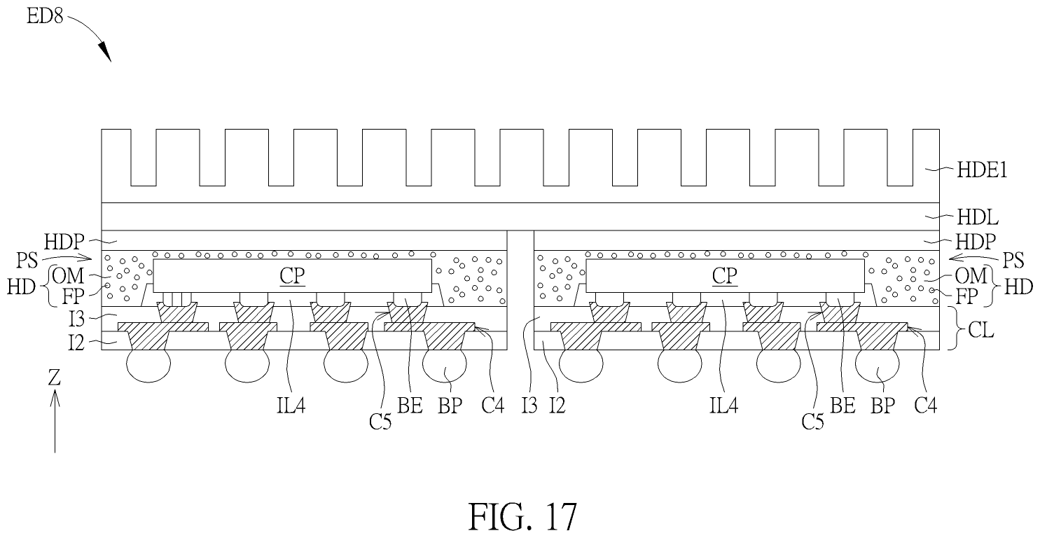

Referring to FIG. 17, FIG. 17 schematically illustrates a cross-sectional view of an electronic device according to an eighth embodiment of the present disclosure. According to the present embodiment, the electronic device ED8 may include a heat dissipation element and a plurality of package structures attached to the heat dissipation element. For example, as shown in FIG. 17, the electronic device ED8 may include the structure formed by attaching two package structures PS to the heat dissipation element HDE1, but not limited thereto. In some embodiments, the heat dissipation element HDE1 of the electronic device ED8 may be replaced with the heat dissipation element HDE (the cooling system) in the above-mentioned embodiments. Specifically, as shown in FIG. 17, the electronic device ED8 may include a plurality of package structures PS respectively be disposed at a side of a heat dissipation element HDP, and the heat dissipation elements HDP may be attached to the heat dissipation element HDE1 through the heat dissipation adhesive HDL, but not limited thereto. Therefore, the heat generated by the chip CP may be conducted and dissipated through the heat dissipation layer HD, the heat dissipation element HDP, the heat dissipation adhesive HDL and the heat dissipation element HDE1. In some embodiments, the electronic device ED8 may not include the heat dissipation element HDP. It some embodiments, plural of copper pillars (bonding elements BE) may correspond to the same portion of the conductive layer C5, but not limited thereto. It should be noted that the electronic device ED8 may include combinations of the above-mentioned heat dissipation elements, which is not limited to the structure shown in FIG. 17. The structure of the package structure PS shown in FIG. 17 may refer to the structure shown in FIG. 14, and will not be redundantly described.

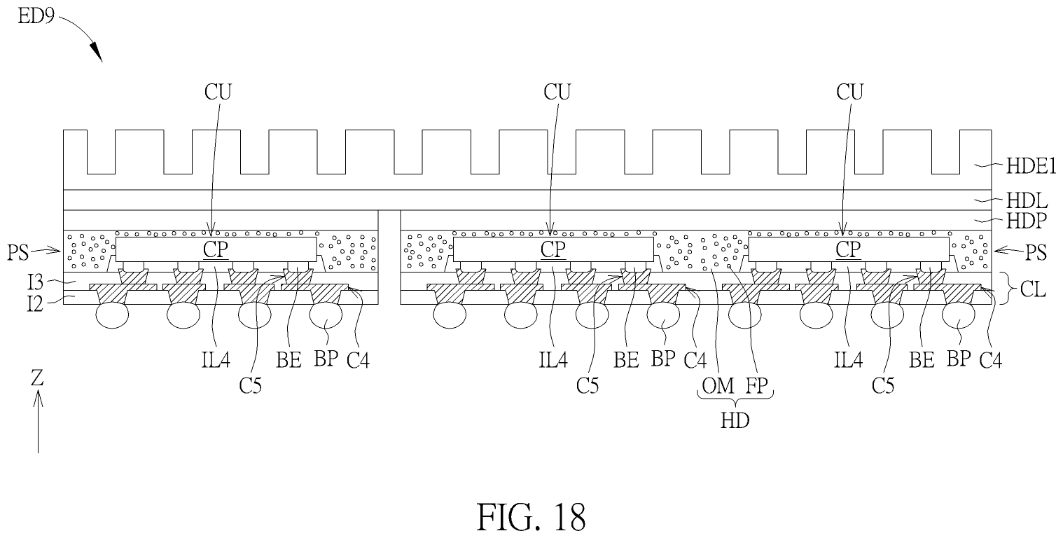

Referring to FIG. 18, FIG. 18 schematically illustrates a cross-sectional view of an electronic device according to a ninth embodiment of the present disclosure. According to the present embodiment, the electronic device ED9 may include a heat dissipation element and a plurality of package structures PS attached to the heat dissipation element, wherein the plurality of package structures PS have different designs. For example, the plurality of package structures PS may include the chip units CU of different numbers. For example, a portion of the package structures PS (shown in the left part of FIG. 18) in the electronic device ED9 may include one chip unit CU and may for example be system on chip; while another portion of the package structures PS (shown in the right part of FIG. 18) in the electronic device ED9 may include multiple chip units CU (for example, two chip units CU) and may for example be system in package, but not limited thereto. The structural features of the package structures PS shown in FIG. 18 may refer to the structure shown in FIG. 14, and will not be redundantly described. In addition, as shown in FIG. 18, in the present embodiment, the surfaces of the conductive layer C4 (back side under bonding metal) in contact with the bonding pads BP may be concave surfaces, but not limited thereto.

In summary, an electronic device and a manufacturing method thereof are provided by the present disclosure, wherein the electronic device includes a chip unit, a circuit structure electrically connected to the chip unit and a heat dissipation layer disposed at a side of the chip unit opposite to the circuit structure. The heat dissipation layer may at least partially contact the rear surface of the chip in the chip unit. Therefore, the heat generated by the chip may be dissipated or conducted to other heat dissipation element(s) through the heat dissipation layer. The heat dissipation layer includes an organic material and silicon carbide particles filled in the organic material, wherein the silicon carbide particles may have monocrystal structure. Therefore, the heat dissipation effect of the heat dissipation layer may be improved, thereby improving the performance or reliability of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
at least one chip unit;
a circuit structure electrically connected to the at least one chip unit; and
a heat dissipation layer disposed at a side of the at least one chip unit opposite to the circuit structure,
wherein the heat dissipation layer includes an insulating material layer and a plurality of silicon carbide particles, the insulating material layer clads the plurality of silicon carbide particles, and the plurality of silicon carbide particles have monocrystal structures.

2. The electronic device of claim 1, wherein a particle size of the plurality of silicon carbide particles is greater than or equal to 0.02 micrometers and less than or equal to 55 micrometers.

3. The electronic device of claim 1, further comprising a bonding pad electrically connected to the at least one chip unit through the circuit structure.

4. The electronic device of claim 1, wherein the at least one chip unit includes a chip, a first insulating layer and a second insulating layer, and the first insulating layer is disposed between the chip and the second insulating layer.

5. The electronic device of claim 4, wherein a thickness of the first insulating layer is less than a thickness of the second insulating layer.

6. The electronic device of claim 4, wherein the first insulating layer comprises inorganic insulating material.

7. The electronic device of claim 4, wherein the second insulating layer comprises organic insulating material.

8. The electronic device of claim 1, further comprising at least one heat dissipation element, wherein the heat dissipation layer is disposed between the at least one heat dissipation element and the circuit structure.

9. The electronic device of claim 8, wherein the at least one heat dissipation element includes water-cooling system.

10. The electronic device of claim 8, wherein the at least one heat dissipation element includes heat sink.

11. The electronic device of claim 1, wherein the insulating material layer comprises organic materials.

12. A manufacturing method of an electronic device, comprising:
providing a carrier and disposing at least one chip unit on the carrier;
forming a circuit structure electrically connected to the at least one chip unit; and
disposing a heat dissipation layer at a side of the at least one chip unit opposite to the circuit structure;
wherein the heat dissipation layer includes an insulating material layer and a plurality of silicon carbide particles, the insulating material layer clads the plurality of silicon carbide particles, and the plurality of silicon carbide particles have monocrystal structures.

13. The manufacturing method of claim 12, wherein the heat dissipation layer contacts a surface of the at least one chip unit opposite to the circuit structure.

14. The manufacturing method of claim 12, wherein the heat dissipation layer surrounds the at least one chip unit.

15. The manufacturing method of claim 12, wherein a thickness of the heat dissipation layer is greater than a thickness of the at least one chip unit.

16. The manufacturing method of claim 12, further comprising following steps before disposing the heat dissipation layer:
forming an encapsulation layer surrounding the at least one chip unit; and
performing a grinding process to the encapsulation layer to remove a portion of the encapsulation layer, thereby planarizing the encapsulation layer or exposing a surface of the at least one chip unit,
wherein the heat dissipation layer contacts the surface of the at least one chip unit after the heat dissipation layer is disposed.

17. The manufacturing method of claim 12, further comprising disposing at least one heat dissipation element at a side of the heat dissipation layer opposite to the at least one chip unit.

18. The manufacturing method of claim 17, wherein the at least one heat dissipation element is attached to the side of the heat dissipation layer through a heat dissipation adhesive.

19. The manufacturing method of claim 17, wherein the at least one heat dissipation element includes water-cooling system or heat sink.

20. The manufacturing method of claim 12, further comprising disposing a bonding pad at a side of the circuit structure.
